(19) United States
(12) Patent Application Publication
(10) Pub. No.: US 2025/0022865 A1
(43) Pub. Date: Jan. 16, 2025

(54) DISPLAY DEVICE AND METHOD FOR MANUFACTURING DISPLAY DEVICE

(71) Applicant: Japan Display Inc., Tokyo (JP)

(72) Inventors: Yoichi KAMIJO, Tokyo (JP); Yoshikatsu IMAZEKI, Tokyo (JP); Koichi MIYASAKA, Tokyo (JP); Shuichi OSAWA, Tokyo (JP); Yoshifumi KAMEI, Tokyo (JP)

(73) Assignee: Japan Display Inc., Tokyo (JP)

(21) Appl. No.: 18/896,908

(22) Filed: Sep. 26, 2024

Related U.S. Application Data
(63) Continuation of application No. PCT/JP2023/009301, filed on Mar. 10, 2023.

(30) Foreign Application Priority Data
Mar. 29, 2022 (JP) 2022-054243

(51) Int. Cl. H01L 25/16; H01L 25/075; H01L 33/00; H01L 33/58; H01L 33/62

(52) U.S. Cl. CPC H01L 25/167; H01L 33/0095; H01L 33/58; H01L 33/62; H01L 25/0753; H01L 2933/0058; H01L 2933/0066

(57) ABSTRACT

A display device includes a substrate provided on a driving circuit, an adhesive layer covering the substrate, a first LED chip provided on the adhesive layer, a pixel circuit provided on the adhesive layer, separated from the first LED chip, a light shielding layer provided on the adhesive layer, and a first opening of the same shape as that of the first LED chip when viewed in a plan view and a second opening of the same shape as that of the pixel circuit when viewed in a plan view, an insulating layer covering the driving circuit and the pixel circuit, and a first wiring provided on the insulating layer, connected to the first LED chip and the pixel circuit, wherein the first wiring overlaps the light shielding layer.

### CROSS-REFERENCE TO RELATED APPLICATIONS

This application is a Continuation of International Patent Application No. PCT/JP2023/009301, filed on Mar. 10, 2023, which claims the benefit of priority to Japanese Patent Application No. 2022-054243, filed on Mar. 29, 2022, the entire contents of each are incorporated herein by reference.

### FIELD

The present invention relates to a display device and a method for manufacturing a display device.

### BACKGROUND

A so-called LED display in which a minute LED chip is arranged in a pixel arranged in a matrix has been developed as a next-generation display. An LED is a self-luminous element similar to an OLED, but unlike the OLED, it is composed of an inorganic compound containing gallium (Ga), indium (In), and the like. Therefore, as compared with an OLED display, it is easy to ensure an LED display with high reliability. Furthermore, the LED has high luminous efficacy and high brightness. Therefore, the LED display is expected as a next-generation display with high reliability, high brightness, and high contrast.

In the LED display, individual LED chips need to be separated from a sapphire substrate (also referred to as an element substrate) on which the LED is formed into individual chips, and the individual chips need to be arranged in a pixel of a circuit substrate (also referred to as a backplane, a TFT substrate). An LED display in which an LED chip is arranged in a concave part arranged in a planarization film is disclosed in U.S. Pat. No. 10, 937, 815.

### SUMMARY

A display device according to an embodiment of the present invention includes a substrate provided on a driving circuit, an adhesive layer covering the substrate, a first LED chip provided on the adhesive layer, a pixel circuit provided on the adhesive layer, separated from the first LED chip, a light shielding layer provided on the adhesive layer, and a first opening of the same shape as that of the first LED chip when viewed in a plan view and a second opening of the same shape as that of the pixel circuit when viewed in a plan view, an insulating layer covering the driving circuit and the pixel circuit, and a first wiring provided on the insulating layer, connected to the first LED chip and the pixel circuit, wherein the first wiring overlaps the light shielding layer.

A method for manufacturing display device includes forming an adhesive layer provided on a substrate with a driving circuit, forming a light shielding layer having a plurality of openings and a liquid repellent surface formed on the adhesive layer, applying a solvent on the adhesive layer within the plurality of openings, arranging a first LED chip in contact with the solvent in a first opening of the plurality of openings, arranging a second LED chip in contact with the solvent in a second opening of the plurality of openings, adhering the adhesive layer to the first LED chip and the pixel circuit to the adhesive layer by evaporating the solvent, forming an insulating layer on the driving circuit, the first LED chip, and the pixel circuit, forming a first contact hole reaching the first LED chip and a second contact hole reaching the pixel circuit in the insulating layer, and forming a first wiring on the insulating layer to connect the first LED chip and the pixel circuit through the first contact hole and the second contact hole.

### BRIEF DESCRIPTION OF DRAWINGS

FIG. 1 is a schematic view of a display device according to an embodiment of the present invention.

FIG. 2 is an enlarged view of a pixel in a display device according to an embodiment of the present invention.

FIG. 3 is a schematic cross-sectional view of a pixel in a display device according to an embodiment of the present invention.

FIG. 4 is a schematic cross-sectional view of a peripheral region and a display region in a display device according to an embodiment of the present invention.

FIG. 5 is a cross-sectional view illustrating a method for manufacturing a display device according to an embodiment of the present invention.

FIG. 6 is a cross-sectional view illustrating a method for manufacturing a display device according to an embodiment of the present invention.

FIG. 7 is a cross-sectional view illustrating a method for manufacturing a display device according to an embodiment of the present invention.

FIG. 8 is a cross-sectional view illustrating a method for manufacturing a display device according to an embodiment of the present invention.

FIG. 9 is a cross-sectional view illustrating a method for manufacturing a display device according to an embodiment of the present invention.

FIG. 10 is a cross-sectional view illustrating a method for manufacturing a display device according to an embodiment of the present invention.

FIG. 11 is a cross-sectional view illustrating a method for manufacturing a display device according to an embodiment of the present invention.

FIG. 12 is a cross-sectional view illustrating a method for manufacturing a display device according to an embodiment of the present invention.

FIG. 13 is a schematic cross-sectional view of a peripheral region and a display region in a display device according to an embodiment of the present invention.

FIG. 14 is a schematic cross-sectional view of a pixel in a display device according to an embodiment of the present invention.

FIG. 15 is a cross-sectional view illustrating a method for manufacturing a display device according to an embodiment of the present invention.

FIG. 16 is a cross-sectional view illustrating a method for manufacturing a display device according to an embodiment of the present invention.

FIG. 17 is a cross-sectional view illustrating a method for manufacturing a display device according to an embodiment of the present invention.

### DESCRIPTION OF EMBODIMENTS

In U.S. Pat. No. 10,937,815, a wiring connected to an LED chip is routed around a display surface side of an LED display. In this case, the routing wiring connected to the LED chip is reflected by light emitted by the LED chip. As a result, the visibility of the LED display is reduced. In addition, when the positional accuracy for mounting the LED chip on a circuit substrate is improved, the manufacturing tact is deteriorated.

In view of the above, an object of an embodiment of the present invention is to provide a display device that suppresses light emitted from the LED chip from being reflected by a metal wiring and improves visibility of an image. Another object of an embodiment of the present invention is to improve manufacturing tact in alignment for mounting the LED chip on the circuit substrate.

Hereinafter, embodiments of the present invention will be described with reference to the drawings. Each of the embodiments is merely an example, and those of ordinary skill in the art can easily conceive of the present invention by appropriately changing it while keeping the gist of the invention and such changes are naturally included in the scope of the present invention. Furthermore, in order to make the description clearer, the drawings may schematically show the width, thickness, shape, and the like of each part in comparison with an actual embodiment. However, the illustrated shapes are merely examples, and do not limit the interpretation of the present invention.

In the embodiments of the present invention, a direction from a substrate toward an LED chip is referred to as “above”, and the opposite direction is referred to as “below”. However, the expression “on” or “under” merely describes the vertical relationship of each element. For example, the expression that the LED chip is arranged on the substrate includes the case where another member is interposed between the substrate and the LED chip. Furthermore, the terms “on” or “under” include not only the case where the elements overlap in a plan a view, but also the case where they do not overlap.

In describing the embodiments of the present invention, elements having similar functions as elements already described will be denoted by the same reference signs or the same reference signs plus a letter of the alphabet or other symbols, and the description thereof may be omitted. Furthermore, when it is necessary to explain a certain element by distinguishing between the respective colors of RGB, a symbol R, G, or B is attached after the reference sign indicating the element to distinguish the element. However, when the element does not need to be described separately for the respective colors of RGB, the description will be made using only the reference sign indicating the element.

### First Embodiment

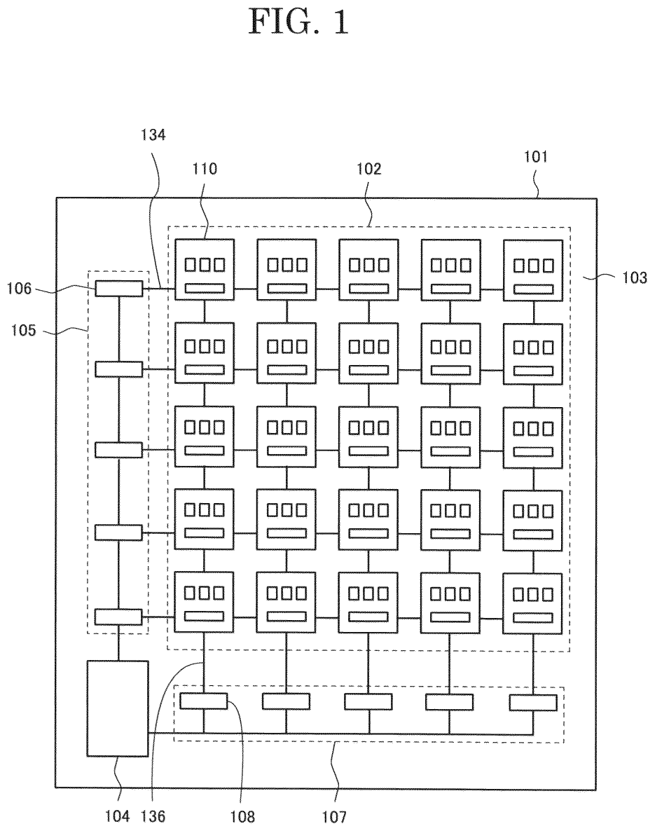

In the present embodiment, a display device 100 according to an embodiment of the present invention will be described with reference to FIG. 1 to FIG. 13. [Outline of Display Device]

FIG. 1 is a schematic view of the display device 100 according to an embodiment of the present invention. The display device 100 includes a substrate 101 having a display region 102 and a peripheral region 103 surrounding the display region 102. A plurality of pixels 110 is arranged in an array in the display region 102. The pixel 110 includes an LED chip and a pixel circuit. A controller 104, a row control circuit 105, and a column control circuit 107 are arranged in the peripheral region 103. In addition, the row control circuit 105 and the column control circuit 107 are also referred to as a driving circuit that drives the pixel 110.

The column control circuit 107 includes a column driver 108 connected to each column of the pixel 110. The column driver 108 is connected to a data line 136 that supplies a data signal in common to all the pixels 110 arranged in the column. In addition, the row control circuit 105 includes a row driver 106 connected to each row of the pixel 110. The row driver 106 is connected to a select line 134 that supplies a select signal in common to all the pixels 110 arranged in the row. The plurality of arrayed pixels 110 is controlled by the controller 104 via the row control circuit 105 and the column control circuit 107.

### [Configuration of Display Device]

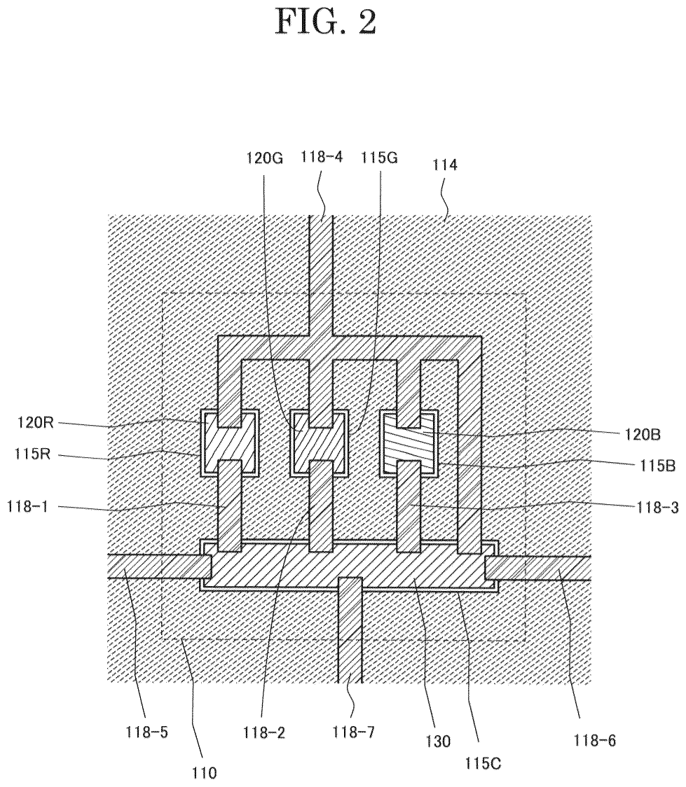

FIG. 2 is an enlarged view of the pixel 110 when the display device 100 is in a plan view. The pixel 110 includes a plurality of LED chips 120 and a pixel circuit 130. For example, the plurality of LED chips 120 includes red, green, and blue LEDs that emit red, green, and blue light. By controlling the LED chips 120R, 120G, and 120B, a full-color pixel 110 can be formed.

The pixel circuit 130 is formed on a substrate separate from the substrate 101. For example, the pixel circuit 130 is a bare chip such as an unpackaged integrated circuit substrate such as a semiconductor substrate.

Although not shown in FIG. 2, the LED chip 120 has two terminals. The two terminals of the LED chip 120 are arranged on the upper surface (upper side) of the LED chip 120. One terminal of the LED chip 120R is connected to the pixel circuit 130 via a wiring 118-1. One terminal of the LED chip 120G is connected to the pixel circuit 130 via a wiring 118-2. One terminal of the LED chip 120B is connected to the pixel circuit 130 via a wiring 118-3. A wiring 118-4 connects the other terminal of the LED chip 120R, the other terminal of the LED chip 120G, and the other terminal of the LED chip 120B, and the pixel circuit 130, respectively. A wiring 118-5 connects the pixel circuit 130 and the pixel circuit 130 of the pixel 110 adjacent in the row direction. A wiring 118-6 connects the pixel circuit 130 and the pixel circuit 130 of the pixel 110 adjacent in the row direction. A wiring 118-7 connects the pixel circuit 130 and the LED chips 120R, 120G, 120B of the pixel 110 adjacent in the column direction, respectively. In this case, the wirings 118-5 and 118-6 connecting the pixel 110 adjacent in the row direction function as select lines. The select line electrically connects the row driver 106 and the pixel circuit 130 of the pixel 110 adjacent in the row direction. The wirings 118-4 and 118-7 connecting the pixel 110 adjacent in the column direction function as data lines. The data line electrically connects the column driver 108 to the LED chip 120 and the pixel circuit 130 of the pixel 110 adjacent in the column direction.

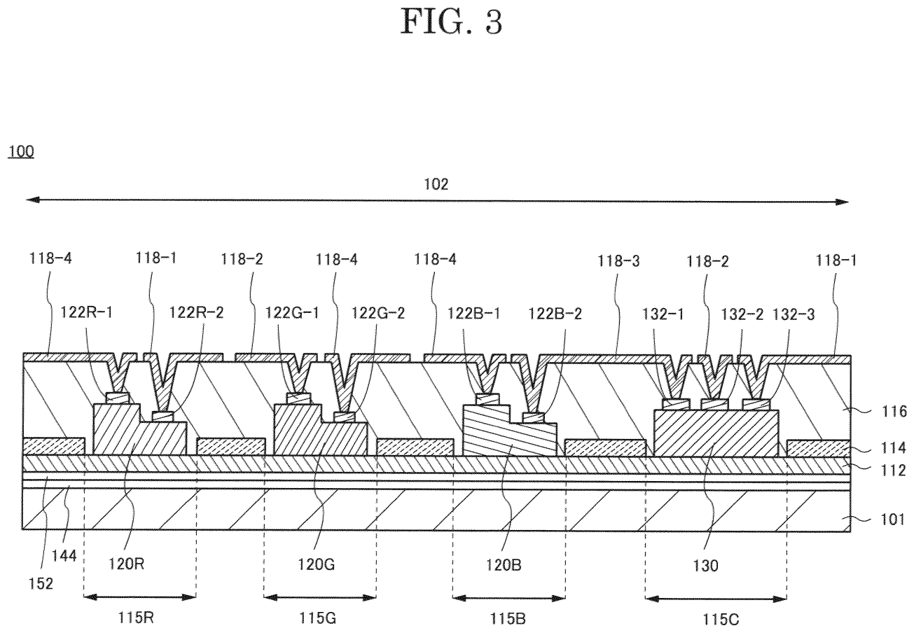

FIG. 3 is a schematic cross-sectional view of the LED chips 120R, 120G, and 120B and the pixel circuit 130. FIG. 3 corresponds to a cross section of the pixel 110, but for ease of explanation, the cross-sectional schematic diagram shown in FIG. 3 does not correspond to a plan view of the pixel 110 shown in FIG. 2.

An insulating layer 144 and an insulating layer 152 are arranged on the substrate 101. For example, a glass substrate, a plastic substrate, a ceramic substrate, or a metal substrate is used as the substrate 101. For example, silicon oxide, silicon nitride, or the like is used as the insulating layer 144 and the insulating layer 152. The insulating layers 144 and 152 will be described in detail later.

In addition, an adhesive layer 112 is arranged on the insulating layer 152. The adhesive layer 112 is arranged on one surface of the substrate 101. In addition, the adhesive layer 112 covers the display region 102 and the peripheral region 103. The adhesive layer 112 fixes the LED chip 120 arranged in the substrate 101. For example, an adhesive layer with sufficient light transmittance in a visible-light region such as a VPA (vinyl sulfonate)-based adhesive layer, a polyimide-based adhesive layer, an acrylic-based adhesive layer, a silicone-based adhesive layer, a polyester-based adhesive layer, or a rubber-based adhesive layer is used as the adhesive layer 112. For example, a thickness of the adhesive layer 112 is 1 μm or more and 5 μm or less. When the thickness is small, the adhesive strength becomes weak, and when the thickness is large, the cost increases, and moreover, an adhesive stain caused by the adhesive layer tends to occur.

The LED chips 120R, 120G, and 120B and the pixel circuit 130 are arranged on the adhesive layer 112. A micro LED or a mini LED is used as the LED chip 120. The micro LED is an LED having a size of 100 μm or less, and the mini LED is an LED having a size of 100 μm to 200 μm. In the display device 100, any size of LED can be used, and may be appropriately used depending on the size of the pixel 110. For example, in the present embodiment, the LED chip 120 is a micro LED, and has a vertical width of 7 μm to 150 μm, a horizontal width of 3 μm to 100 μm, and a height of about 3 μm to 15 μm. The LED chip 120 is arranged such that terminals 122-1 and 122-2 are arranged on the upper side. For example, the terminals 122-1 and 122-2 are formed of a conductive material such as gold (Au), copper (Cu), silver (Ag), tin (Sn), or aluminum (Al). The same applies to the LED chips 120G and 120B and the pixel circuit 130. The LED chip 120 emits light to the substrate 101 side. Therefore, the substrate 101 side becomes the display surface of the display device 100.

A light-shielding layer 114 is arranged on the adhesive layer 112. The light-shielding layer 114 is a black film with insulating properties. The light-shielding layer 114 is also referred to as a black matrix. The light-shielding layer 114 has a plurality of openings 115. The plurality of openings 115 corresponds to positions where the LED chips 120R, 120G, and 120B and the pixel circuit 130 are arranged, respectively. As shown in FIG. 2, the light-shielding layer 114 has an opening 115R in which the LED chip 120R is arranged, an opening 115G in which the LED chip 120G is arranged, an opening 115B in which the LED chip 120B is arranged, and an opening 115C in which the pixel circuit 130 is arranged. In addition, the shape when the opening 115R is in a plan view is substantially the same as the shape when the LED chip 120R is in a plan view. A thickness of the light-shielding layer 114 is preferably thinner than a height of the LED chip 120. For example, if the height of the LED is about 3 μm, the thickness of the light-shielding layer 114 may be 3 μm or less.

An insulating layer 116 is arranged to cover the light-shielding layer 114, the LED chips 120R, 120G, and 120B, and the pixel circuit 130. The insulating layer 116 is not illustrated in FIG. 2. For example, an organic resin material such as polyimide, polyamide, acryl, or epoxy may be used as the insulating layer 116. For example, an inorganic material such as silicon oxide or silicon nitride may be used as the insulating layer 116. For example, the insulating layer 116 may be SOG (Spin on Glass). In addition, a film of an inorganic material and a film of an organic resin material may be combined as the insulating layer 116. In the case where an organic resin material is used as the insulating layer 116, the organic resin material functions as a planarization film, and unevenness on the surface caused by the LED chips 120R, 120G, and 120B and the pixel circuit 130 can be reduced. A plurality of contact holes that expose the two terminals 122-1 and 122-2 of the LED chip 120 and terminals 132-1 and 132-2 of the pixel circuit 130 is arranged in the insulating layer 116.

As shown in FIG. 3, a plurality of wirings 118-1 to 118-6 is arranged on the insulating layer 116. For example, in FIG. 3, the wiring 118-4 connects a terminal 122B-2 of the LED chip 120B and the terminal 132-1 of the pixel circuit 130. Although the wirings 118-1 to 118-6 are not described in detail, they connect the LED chip 120 and the pixel circuit 130 as described in FIG. 2. The wirings 118-1 to 118-7 shown in FIG. 2 and FIG. 3 supply a signal for controlling light emission to the respective LED chips 120R, 120G, and 120B.

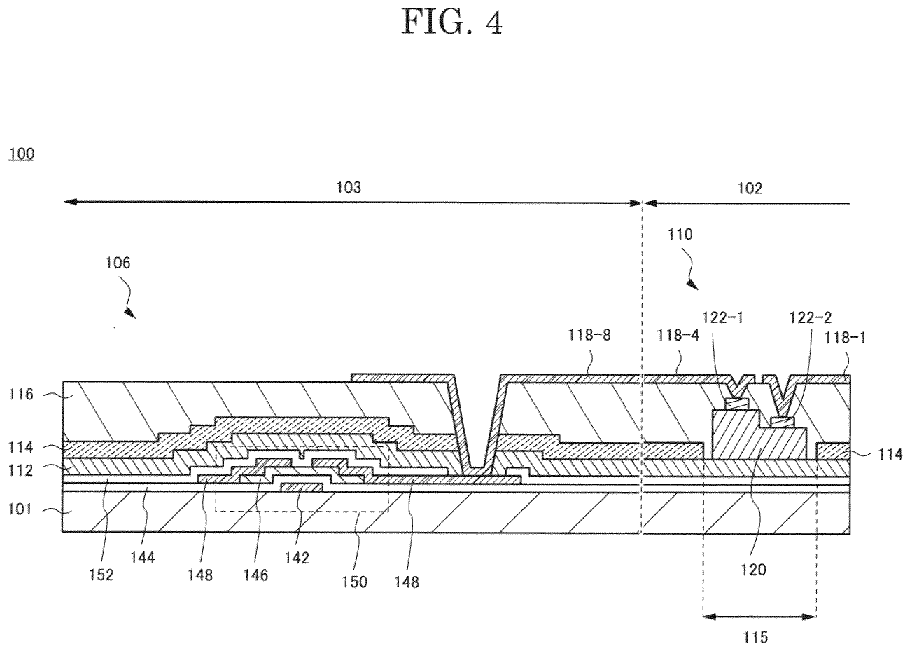

FIG. 4 is a cross-sectional view in the peripheral region 103 and the display region 102. FIG. 4 shows the row driver 106 in the peripheral region 103. For example, the row driver 106 and the column driver 108 are circuits constituted by a plurality of transistors 150. A known transistor may be used as the transistor 150. In the present embodiment, the transistor 150 is a bottom-gate transistor. The transistor 150 includes a gate electrode 142, the insulating layer 144 functioning as a gate insulating layer, a semiconductor layer 146, and source/drain electrodes 148-1 and 148-2. In addition, the insulating layer 152 that functions as a passivation is arranged on the transistor 150.

One of the plurality of wirings 118 connects the pixel 110 and the row driver 106. For example, as shown in FIG. 4, in the peripheral region 103, a wiring 118-8 connects the source/drain electrode 148-2 of the transistor 150 constituting the row driver 106 and the pixel circuit 130 of the pixel 110. In addition, the other one of the plurality of wirings 118 connects the pixel 110 and the column driver 108. In the peripheral region 103, the wiring 118 is connected to the source/drain electrode 148-2 of the transistor 150 constituting the column driver 108. As shown in FIG. 4, the adhesive layer 112 and the light-shielding layer 114 are also arranged in the peripheral region 103. The adhesive layer 112 and the light-shielding layer 114 cover the column control circuit 107, the row control circuit 105, and the controller 104. The wiring 118 and the source/drain electrode 148-2 are connected via a contact hole formed in the insulating layer 116, the light-shielding layer 114, the adhesive layer 112, and the insulating layer 152. In addition, although an example in which the adhesive layer 112 and the light-shielding layer 114 are arranged in the peripheral region 103 is shown in FIG. 4, an embodiment of the present invention is not limited to this. The adhesive layer 112 and the light-shielding layer 114 may be arranged in the display region 102, and both the adhesive layer 112 and the light-shielding layer 114 may not be arranged in the peripheral region 103. In addition, the adhesive layer 112 and the light-shielding layer 114 may be arranged in the display region 102, and the adhesive layer 112 or the light-shielding layer 114 may be arranged in the peripheral region 103.

For example, a metal such as aluminum or copper is used as the wiring 118. The gate electrode 142, the source/drain electrodes 148-1 and 148-2, wirings for routing the gate electrode 142, and the source/drain electrodes 148-1 and 148-2 are also made of a metal such as aluminum or copper. Such metal wiring reflects the light emitted from the LED chip and reduces the visibility of the image. In addition, contrast is reduced due to the mixing of colors of the light emitted by the LED chip.

In the display device 100 according to an embodiment of the present invention, the light-shielding layer 114 is arranged in a region other than the region where the LED chips 120R, 120G, and 120B and the pixel circuit 130 are arranged. That is, in the display region 102, a gap arranged by the LED chips 120, 120G, 120B, and the pixel circuit 130 is filled with the light-shielding layer 114. In addition, terminals of the LED chip 120 are arranged above. Therefore, the plurality of wirings 118 is routed above the light-shielding layer 114. Therefore, in the display region 102, the wiring arranged below the LED chips 120R, 120G, and 120B can be omitted. In the display device 100, since the display surface is the lower side of the substrate 101, the plurality of wirings 118 routed in the display region 102 can be shielded by the light-shielding layer 114. As a result, the light emitted from the LED chips 120R, 120G, and 120B is suppressed from being reflected by the metal wiring 118, so that it is possible to provide the display device 100 in which the visibility of the image is improved. In addition, since a region where the driving circuit is arranged is spaced apart from the region where the LED chip 120 is arranged, the influence of the light emitted from the LED chip 120 can be reduced.

### [Method for Manufacturing Display Device]

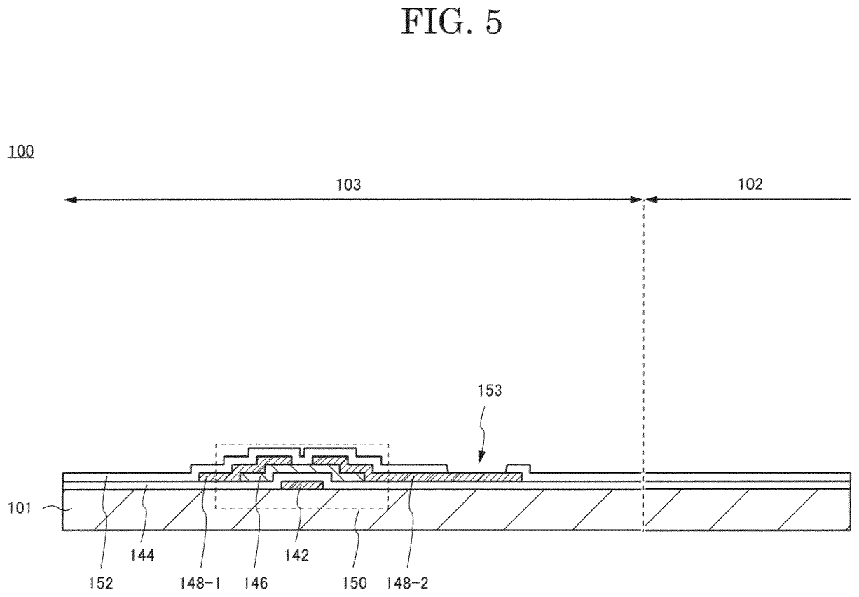

Next, a method for manufacturing the display device 100 according to an embodiment of the present invention will be described with reference to FIG. 5 to FIG. 12.

FIG. 5 is a diagram illustrating a step of forming the transistor 150 and the insulating layer 152 constituting the driving circuit in the peripheral region 103 on the substrate 101. FIG. 5 is a cross-sectional view in the display region 102 and the peripheral region 103. In a method of forming the transistor 150, a known method of forming a transistor is applied to form the gate electrode 142, the insulating layer 144, the semiconductor layer 146, and the source/drain electrodes 148-1 and 148-2. Through the above steps, the driving circuit is formed. Thereafter, the insulating layer 152 functioning as a passivation layer is formed on the transistor 150. For example, a single layer of silicon oxide or silicon nitride, or a stacked layer of silicon oxide and silicon nitride may be used as the insulating layer 152. In this case, the insulating layer 144 and the insulating layer 152 are also arranged in the display region 102. Next, an opening 153 exposing part of the source/drain electrode 148-2 is formed in the insulating layer 152.

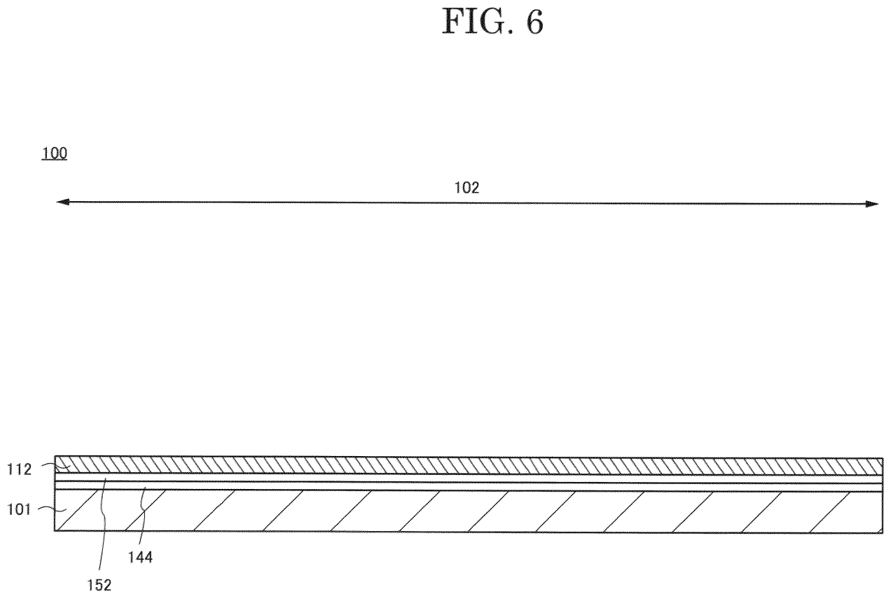

FIG. 6 is a diagram illustrating a step of forming the adhesive layer 112 on the insulating layer 152. FIG. 6 is a cross-sectional view in the display region 102. The adhesive layer 112 is formed not only in the display region 102 but also in the peripheral region 103. For example, an adhesive layer with sufficient light transmittance in a visible-light region such as a VPA adhesive layer, a polyimide-based adhesive layer, an acryl-based adhesive layer, a silicone-based adhesive layer, a polyester-based adhesive layer, or a rubber-based adhesive layer is used as the adhesive layer 112. A method of applying the adhesive layer 112 is not particularly limited, and for example, spin coating, slit coating, ink jet coating, roll coating, or the like is used. For example, a thickness of the adhesive layer 112 is 1 μm or more and 5 μm or less. The adhesive layer 112 may be a thermosetting material or an ultraviolet curable material. The adhesive layer 112 may be processed into any shape by patterning using the ultraviolet curable material.

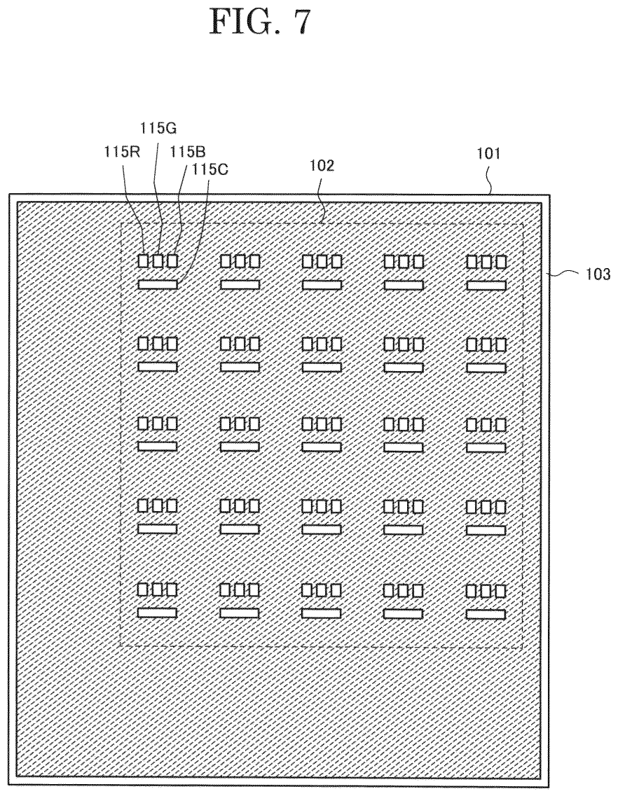

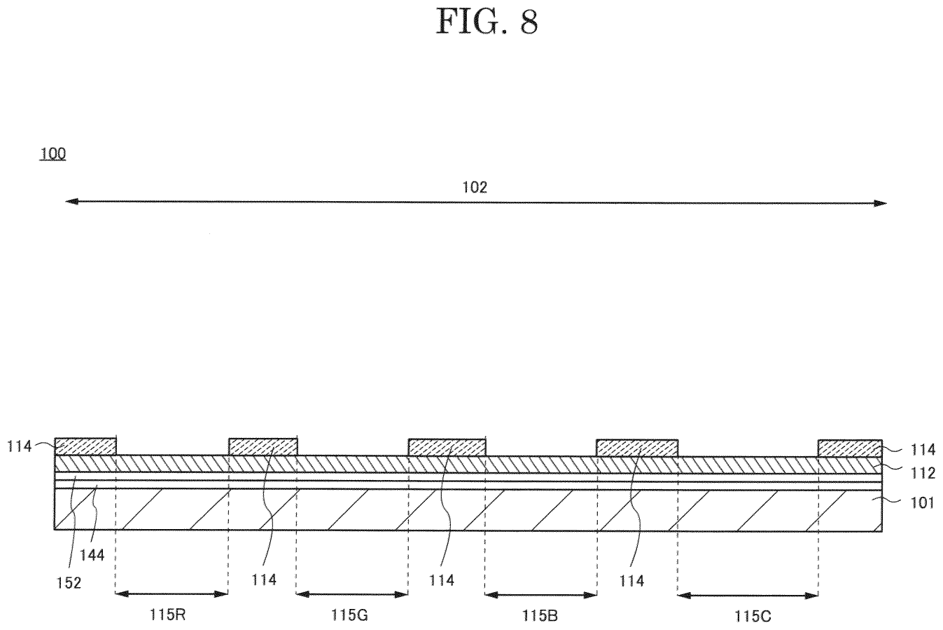

FIG. 7 and FIG. 8 are diagrams illustrating a step of forming the light-shielding layer 114 on the adhesive layer 112. FIG. 7 is a plan view when the substrate 101 is in a plan view, and FIG. 8 is a cross-sectional view when the display region 102 is viewed in a cross-section. The light-shielding layer 114 is formed not only in the display region 102 but also in the peripheral region 103. As described above, the thickness of the light-shielding layer 114 is determined according to the height of the LED chip 120.

As shown in FIG. 7, the light-shielding layer 114 has a plurality of openings 115R, 115G, 115B, and 115C. The LED chip 120R, the LED chip 120G, and the LED chip 120B are subsequently arranged in each of the plurality of openings 115R, 115G, and 115B. The pixel circuit 130 is subsequently arranged in the opening 115C. Therefore, the area of the openings 115R, 115G, 115B, and 115C is preferably slightly larger than the area of the LED chip 120 and the area of the pixel circuit 130. For example, the shape when the opening 115R is in a plan view is preferably 1.05 times to 1.5 times the shape when the LED chip 120R is in a plan view. The relationship between the LED chips 120G and 120B and the pixel circuit 130 and the openings 115G, 115B, and 115C is also the same as the relationship between the LED chip 120R and the opening 115R.

In a later step, a solvent must be applied to adhere the LED chip 120 and the pixel circuit 130 to the substrate 101. However, if a solvent is applied to the light-shielding layer 114, it is difficult to accurately bond the LED chip 120 and the pixel circuit 130 to the inside of the opening 115. Therefore, it is preferable that the light-shielding layer 114 has liquid repellency. In other words, a surface contact angle of the light-shielding layer 114 is preferably larger than a surface contact angle of the adhesive layer 112 inside the opening 115. For example, the surface contact angle of the light-shielding layer 114 is preferably 85° or more. Since the light-shielding layer 114 has liquid repellency, it becomes easy to apply the solvent to a desired region when applying the solvent later.

The liquid repellency of the light-shielding layer 114 can be enhanced by containing a fluorine-containing compound in a black resin (for example, a cardo resin, a low-molecular-weight acryl resin, or the like) having a high insulating property. The liquid repellency of the light-shielding layer 114 can be adjusted by the content of the fluorine-containing compound. The greater the amount of the fluorine-containing compound, the higher the liquid repellency of the light-shielding layer 114. The fluorine-containing compound is a compound containing a fluorine atom.

For example, in the case where the light-shielding layer 114 is applied by injection, a liquid-repellent component may be added to a black resist. The liquid repellent component refers to a surfactant containing fluorine. The fluorine surfactant is uniformly mixed in liquid form but tends to migrate and segregate to the top layer of the film when applied or dried. Utilizing this property and adding the fluorine surfactant to the black resist, only the liquid repellency of the upper layer of the light-shielding layer 114 can be enhanced when the black resist is applied and dried.

In addition, after the light-shielding layer 114 is formed, a fluororesin may be formed on the light-shielding layer 114 by a so-called lift-off method. For example, a pattern is formed in the opening 115 using a resist. Next, a fluororesin is formed on the light-shielding layer 114 and the pattern using the resist, and then the resist is removed. Therefore, a fluororesin may be formed on the light-shielding layer 114.

In addition, after forming the black resin having insulating properties as the light-shielding layer 114, the surface of the light-shielding layer 114 may be subjected to a plasma treatment using a gas containing fluorine or a fluorine compound (for example, CF₄). For example, after a mask is formed on the opening 115, the light-shielding layer 114 is exposed to an atmosphere in which a plasma containing fluorine is formed. A fluorine compound is formed on the light-shielding layer 114. As a result, the liquid repellency of the surface of the light-shielding layer 114 may be higher than that of the surface of the adhesive layer 112 in the opening 115.

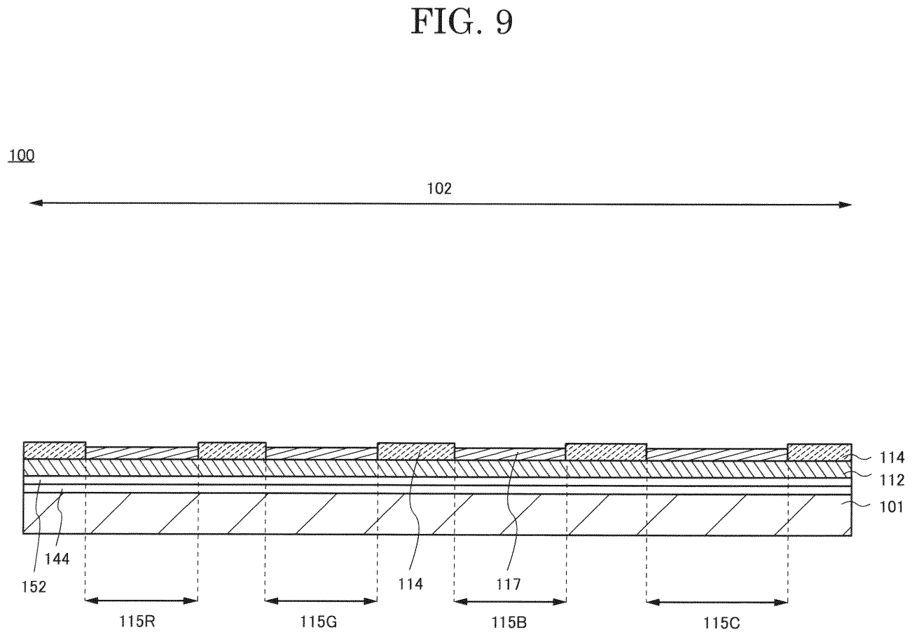

FIG. 9 is a diagram illustrating a step of applying a solvent 117 to the opening 115 of the light-shielding layer 114. The solvent 117 includes a flux activator. For example, the flux activator described in Japanese laid-open patent publication No. 2014-57019 can be used as the flux activator. For example, the solvent 117 may be dropped into the opening 115 of the light-shielding layer 114 by an ink jet method. In addition, an electrostatic dispensing method or a precision dispenser method may be used as a method of applying the solvent 117 in addition to the injection method.

As described in FIG. 8, the light-shielding layer 114 has liquid repellency. Therefore, even if the solvent 117 is applied to the surface of the light-shielding layer 114, the solvent 117 is repelled by the surface of the light-shielding layer 114, so that the solvent 117 can be selectively arranged inside the opening 115.

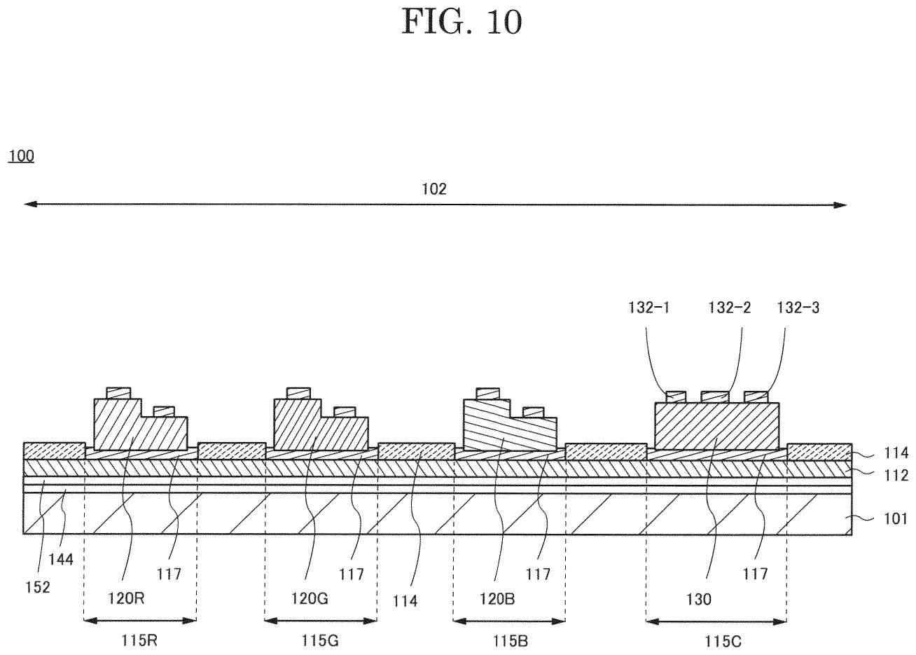

FIG. 10 is a diagram illustrating a step of arranging the LED chip 120R, the LED chip 120G, the LED chip 120B and the pixel circuit 130 on the plurality of openings 115 of the light-shielding layer 114. In the present embodiment, the solvent 117 is selectively arranged inside the plurality of openings 115. After the LED chip 120 is picked up from an element substrate, the LED chip 120 is released on the solvent 117 and dropped. In addition, the release timing is a timing at which the lower surface of the LED chip 120 contacts the solvent 117. At this time, since the solvent 117 and the LED chip 120 are in contact with each other, the LED chip 120 can be smoothly transferred onto the solvent 117. For holding, transferring, and releasing the LED chip 120, a device (for example, a chip mounter or the like) capable of sucking the upper surface of the LED chip 120 and releasing the suction as needed is used. In addition, a substrate for transfer may be used to pick up the plurality of LED chips from the element substrate, the substrate for transfer and the circuit substrate may be bonded together, and then the LED chip 120 is separated from the carrier substrate to arrange the LED chip 120 in the opening 115. Furthermore, the pixel circuit 130 is also arranged on the solvent 117 in the same manner as the LED chip 120.

The position of the LED chip 120 arranged on the solvent 117 fluctuates for a while in association with the fluctuation of the solvent 117. After a certain period of time, the shape of the solvent 117 becomes stable, so that the position of the LED chip 120 also converges to a predetermined position. In this case, the opening 115 of the light-shielding layer 114 in which the solvent 117 is arranged is a region where the outline of the LED chip 120 is projected, as described above. Therefore, the position where each LED chip 120 converges is a position that substantially coincides with the opening 115. By forming the solvent 117 in the opening 115 in this manner, the position of the LED chip 120 can be determined spontaneously and accurately using the surface tension of the solvent 117.

By positioning the LED chip 120 and the pixel circuit 130 as described above, it is possible to suppress a positional deviation when the LED chip 120 or the pixel circuit 130 is mounted on the substrate 101. As a result, the positional accuracy of the LED chip 120R, the LED chip 120G, the LED chip 120B, and the pixel circuit 130 can be improved.

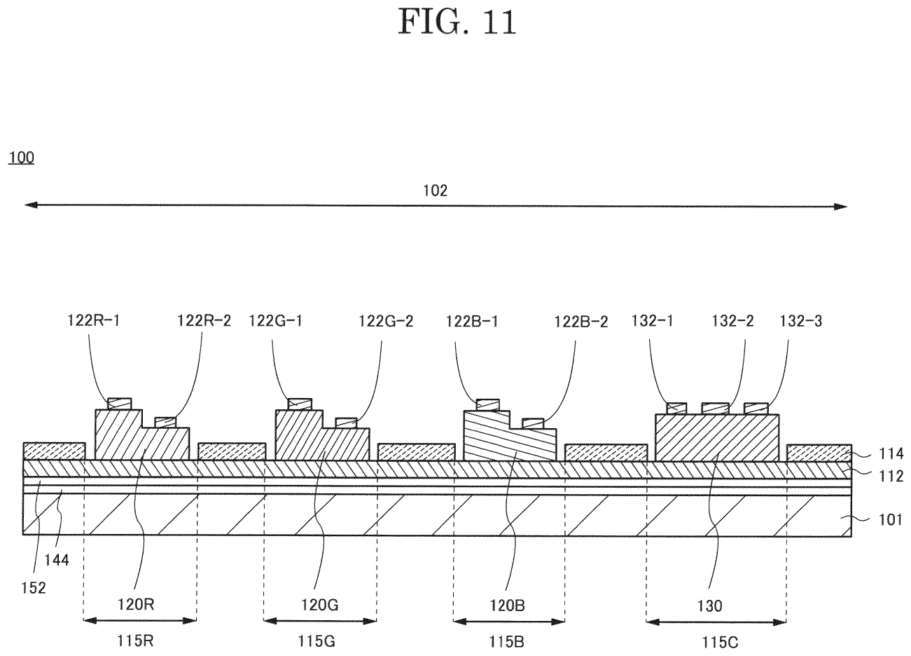

FIG. 11 is a diagram illustrating a step of drying the solvent 117. For example, in the drying step, the substrate 101 is heated at about 100° C. to evaporate the solvent 117. As a result, the flux activator remains between the adhesive layer 112 and the LED chip 120 and between the adhesive layer 112 and the pixel circuit 130. As a result, the LED chip 120R, the LED chip 120G, the LED chip 120B, and the pixel circuit 130 can be fixed to the adhesive layer 112. Furthermore, in the present embodiment, a height of the LED chip 120R, a height of the LED chip 120G, and a height of the LED chip 120B are substantially the same.

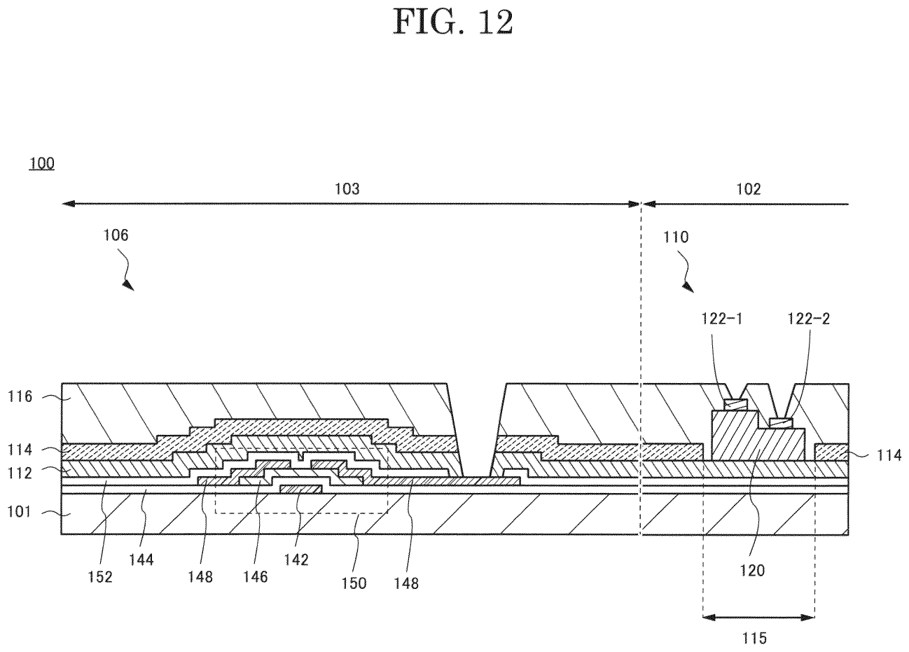

FIG. 12 is a diagram illustrating a step of forming the insulating layer 116 on the LED chip 120 and the pixel circuit 130. The insulating layer 116 is formed in the display region 102 and the peripheral region 103. For example, an organic resin material such as acryl, polyimide, polyamide, or epoxy is used as the insulating layer 116. A thickness of the insulating layer 116 may be any thickness as long as it covers the LED chip 120R, the LED chip 120G, the LED chip 120B, and the pixel circuit 130, and is, for example, 5 μm or more and 17 μm or less. Next, in the display region 102, a contact hole is formed in the insulating layer 116 to expose the terminals 122-1 and 122-2 of the LED chip 120. In the peripheral region 103, a contact hole is formed in the insulating layer 116, the light-shielding layer 114, and the adhesive layer 112 to expose the source/drain electrode 148-2. A depth of the contact hole formed in the display region 102 is different from the depth of the contact hole formed in the peripheral region 103. Therefore, the formation of the contact hole in the display region 102 and the formation of the contact hole in the peripheral region 103 are preferably performed in different steps. In addition, although the case where the opening 153 is formed in the insulating layer 152 in advance has been described in the present embodiment, the present embodiment is not limited to this. When etching the insulating layer 116, the light-shielding layer 114, the adhesive layer 112, and the insulating layer 152, the contact holes may be collectively formed.

Finally, the wiring 118 is formed on the insulating layer 116. For example, a metal such as aluminum or copper is used as the wiring 118. A conductive film is formed on the insulating layer 116 and is appropriately patterned to form the wiring 118. As a result, the LED chip 120 and the pixel circuit 130 can be connected. In addition, the pixel circuit 130 and the driving circuit may be connected.

Through the above steps, the display device 100 according to an embodiment of the present invention can be manufactured.

In the present embodiment, although the case where the contact holes for exposing the source/drain electrode 148-2 are formed in the insulating layer 116, the light-shielding layer 114, and the adhesive layer 112 in the peripheral region 103 has been described in the step shown in FIG. 12, the present embodiment is not limited to this. For example, in the steps shown in FIG. 7 and FIG. 8, the opening may be formed in the light-shielding layer 114 in the peripheral region 103, and in the step shown in FIG. 12, the contact hole for exposing the source/drain electrode 148-2 may be formed in the opening.

In the method for manufacturing the display device 100 according to an embodiment of the present invention, the solvent 117 applied to the surface of the light shielding layer is repelled by imparting liquid repellency to the surface of the light shielding layer. As a result, the solvent 117 can be accurately arranged in the opening of the light shielding layer. After the LED chip 120 and the pixel circuit 130 are arranged on the solvent 117, the position of the LED chip and the pixel circuit is converged to a predetermined position as the form of the solvent 117 is stabilized. As a result, positioning of the LED chip 120 and the pixel circuit 130 can be accurately performed in a short time. As described above, in the method for manufacturing the display device 100, the manufacturing tact in the alignment for mounting the LED chip and the pixel circuit on the substrate can be improved.

In addition, although an example in which a circuit configured by the transistor 150 is used as the row driver 106 or the column driver 108 is described in the present embodiment, an embodiment of the present invention is not limited to this. For example, a bare chip 140 such as an unpackaged integrated circuit substrate such as a semiconductor substrate may be used as the row driver 106 and the column driver 108.

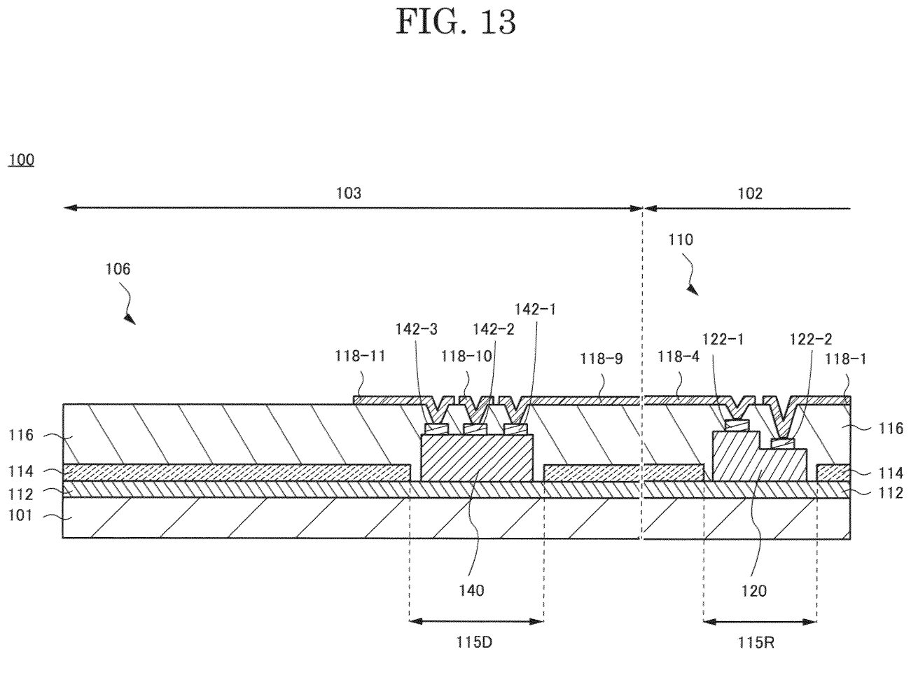

FIG. 13 shows a cross-sectional view in the peripheral region 103 and the display region 102 in the case where the bare chip 140 is used as the row driver 106. In the case where the bare chip 140 is used for each of the row driver 106 and the column driver 108, the adhesive layer 112 and the light-shielding layer 114 are arranged on the substrate 101. An opening 115D is arranged in the light-shielding layer 114. The bare chip 140 is arranged in the opening 115. A plurality of terminals 142-1 to 142-3 is arranged in the bare chip 140. A wiring 118-9 connects the terminal 142-1 of the bare chip 140 and the pixel circuit 130 of the pixel 110. A wiring 118-10 connects the terminal 142-2 of the bare chip 140 and the terminal of the bare chip 140 of the adjacent row driver 106. A wiring 118-11 connects the terminal 142-3 of the bare chip 140 and the terminal of the controller 104.

In the case where the bare chip 140 is used for each of the row driver 106 and the column driver 108, there is no need to form a transistor in the substrate 101. Furthermore, in the case where the bare chip is used for each of the row driver 106 and the column driver 108, the insulating layer 144 and the insulating layer 152 may be omitted as appropriate, and the adhesive layer 112 may be formed on the substrate 101. When forming the plurality of openings 115R, 115G, 115B, and 115C in the light-shielding layer 114, the opening 115D for arranging the bare chip 140 may be formed. Since the subsequent steps can be performed in the same manner as the manufacturing steps of the display region 102 described with reference to FIG. 9 to FIG. 11, the manufacturing steps of the display device 100 can be simplified.

### Second Embodiment

Although it has been described that the height of the LED chip 120R, the height of the LED chip 120G, and the height of the LED chip 120B are generally the same, an embodiment of the present invention is not limited to this. The height of the LED chip 120R, the height of the 120G of LED chip, and the height of the ELD chip 120B may be different for each color. The heights of the LED chips 120R, 120G, and 120B may vary from 8 μm to 12 μm due to structural differences and the like. Since the heights of the LED chips 120R, 120G, 120B are different from each other, the connecting surface between the terminals 122-1 and 122-2 and the wiring 118 is not uniform. In addition, the depths of the contact holes formed in the insulating layer 116 are different between the terminal of the LED chip 120 having a smaller height and the terminal of the LED chip 120 having a larger height. Therefore, it is difficult to form a contact hole corresponding to the height of the LED chip 120 in the insulating layer 116, or the wiring may be broken when the wiring 118 is formed.

Therefore, in the case where the heights of the LED chips 120R, 120G, and 120B are different for each color, it is preferable to adjust the thickness of the adhesive layer 112 to make the connecting surface between the terminals 122-1 and 122-2 and the wiring 118 uniform.

### [Configuration of Display Device]

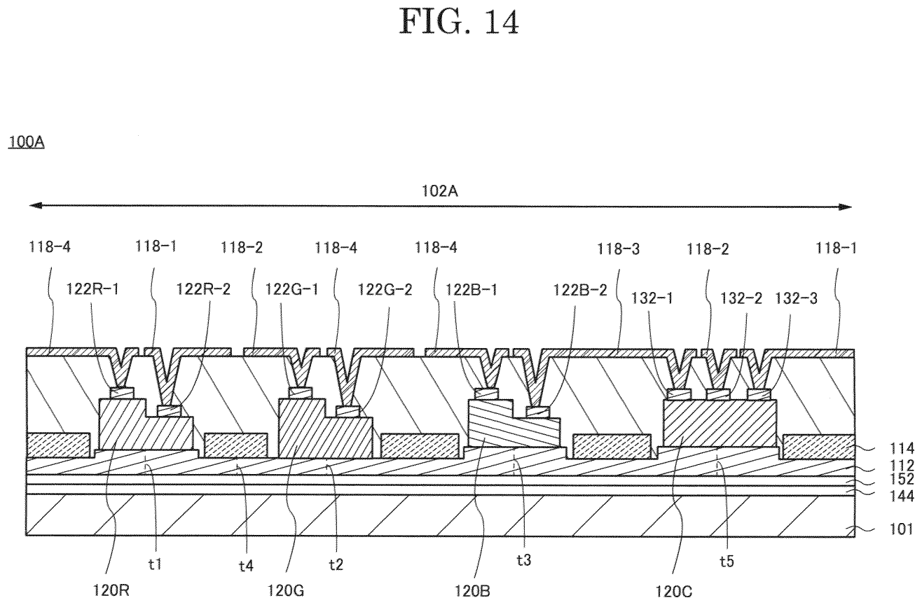

FIG. 14 is a cross-sectional view of the pixel 110 in a display device 100A according to an embodiment of the present invention. FIG. 14 corresponds to a cross section of the pixel 110, but for ease of explanation, the schematic cross-sectional view shown in FIG. 14 does not correspond to a plan view of the pixel 110 shown in FIG. 2.

In the present embodiment, as shown in FIG. 14, the height of the LED chip is increased in the order of the LED chip 120B, the LED chip 120R, and the LED chip 120G. In this case, the thickness of the adhesive layer 112 in a region where the LED chips 120R, 120G, and 120B are arranged is adjusted so that the connecting surface between the terminal and the wiring 118 in the LED chips 120R, 120G, and 120B is uniform. In FIG. 14, the thickness of the adhesive layer 112 inside the opening 115R in which the LED chip 120R is arranged is referred to as a thickness t1. The thickness of the adhesive layer 112 inside the opening 115G in which the LED chip 120G is arranged is defined as a thickness t2. The thickness of the adhesive layer 112 inside the opening 115B in which the LED chip 120B is arranged is defined as a thickness t3. The thickness of the adhesive layer 112 overlapping the light-shielding layer 114 is defined as a thickness t4. The thickness of the adhesive layer 112 inside the opening 115C in which the pixel circuit 130 is arranged is defined as a thickness t5.

As described above, in the present embodiment, the height increases in the order of the LED chips 120B, 120R, and 120G. Therefore, the thickness of the adhesive layer 112 is adjusted so that the thickness of the adhesive layer 112 increases in the order of the thickness t2, the thickness t1, and the thickness t3. In addition, depending on the height of the LED chip 120G, the thickness t2 and the thickness t4 may be the same size, or the thickness t2 may be greater than the thickness t4. Although FIG. 14 shows the case where the thickness t5 is greater than the thickness t3, the thickness t5 may be appropriately set depending on the height of the pixel circuit 130. Therefore, in the case where the height of the terminal of the pixel circuit 130 is different from the heights of the LED chips 120R, 120G, and 120B, the thicknesses t1 to t5 may be adjusted. This makes it possible to make the connecting surface between the terminals of the LED chips 120R, 120G, and 120B and the pixel circuit 130 and the wiring 118 uniform.

### [Method for Manufacturing Display Device]

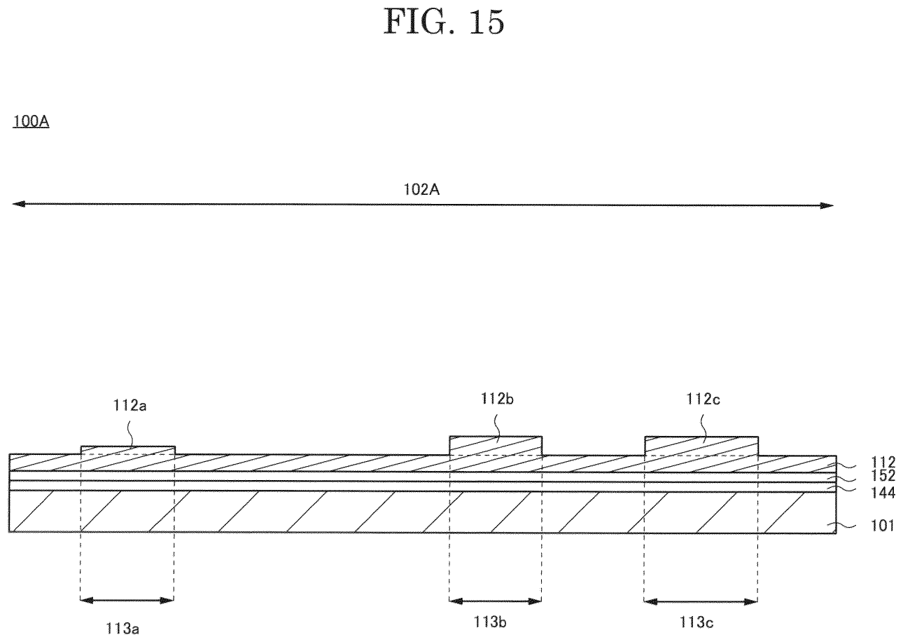

A method for manufacturing the display device 100A shown in FIG. 14 will be described with reference to FIG. 4, FIG. 5, FIG. 9 to FIG. 12, and FIG. 15 to FIG. 17. In addition, a detailed description of steps similar to those of the first embodiment will be omitted.

The step of forming the transistor 150 and the insulating layer 152 on the substrate 101 is similar to the step shown in FIG. 4.

In the present embodiment, in order to adjust the thickness of the adhesive layer 112 inside the openings 115R, 115G, 115B, and 115C, for example, a photoresist with adhesive properties is used as the adhesive layer 112. For example, the above-described VPA (vinyl sulfonate)-based adhesive layer may be used as the photoresist with adhesive properties.

First, similar to the step shown in FIG. 5, the adhesive layer 112 having a uniform thickness is formed on the insulating layer 152. Next, as shown in FIG. 15, adhesive layers 112a, 112b, and 112c are partially formed. A region 113b where the adhesive layer 112a is formed is a region where the LED chip 120R is arranged, a region 113b where the adhesive layer 112b is formed is a region where the LED chip 120B is arranged, and a region 113c where the adhesive layer 112c is formed is a region where the pixel circuit 130 is arranged. In addition, in FIG. 15, the adhesive layer 112a, the adhesive layer 112b, and the adhesive layer 112c have increasing thickness in this order. The thicknesses of the adhesive layer 112a, the adhesive layer 112b, and the adhesive layer 112c vary depending on the heights of the LED chips 120R, 120G, and 120B and the pixel circuit 130 to be arranged later. Other regions are regions where the light-shielding layer 114 and the LED chip 120G are arranged. Using a photoresist with adhesive properties as the adhesive layer 112 makes it possible to form the adhesive layer 112 with a different thickness in a predetermined region. If necessary, an adhesive layer may be partially formed in the region where the LED chip 120G is arranged.

For example, in a method of forming the adhesive layer 112 having a different thickness, an adhesive layer is formed in each of the regions 113a, 113b, and 113c with a predetermined thickness, and then an adhesive layer is formed in each of the regions 113b and 113c with a predetermined thickness, and finally, an adhesive layer is formed in the region 113c with a predetermined thickness. As a result, the adhesive layer 112 in which the adhesive layers 112a, 112b, and 112c are arranged can be formed.

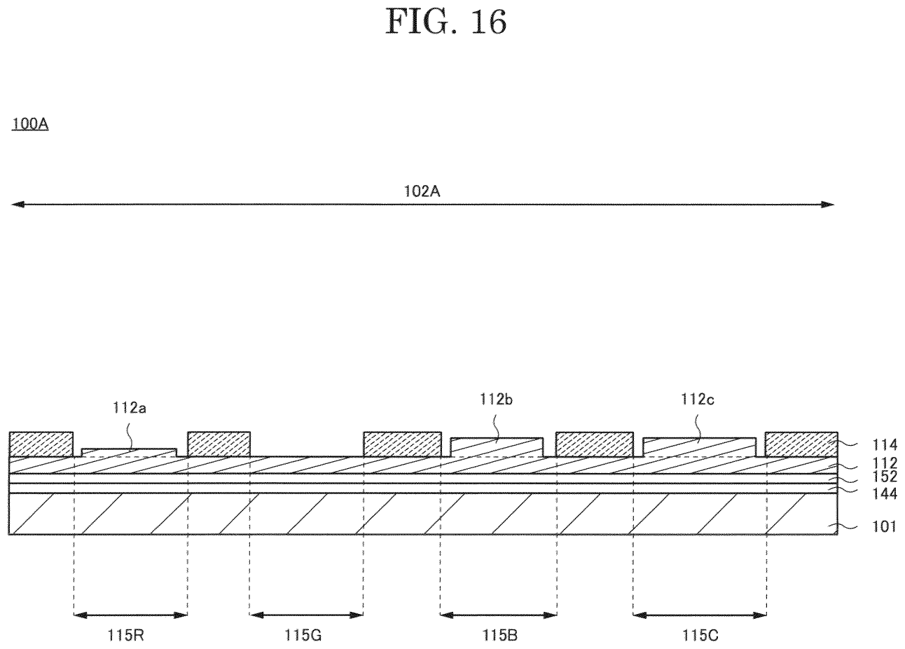

FIG. 16 is a diagram illustrating a step of forming the light-shielding layer 114 on the adhesive layer 112. As shown in FIG. 16, the thickness of the light-shielding layer 114 is preferably greater than that of the adhesive layer 112c, which is the thickest among the adhesive layers 112a, 112b, and 112c. This is because the solvent 117 overflows from the opening 115 of the light-shielding layer 114 when the thickness of the light-shielding layer 114 is thinner than the thickness of the adhesive 112c.

Since the steps of arranging the LED chip 120 and the pixel circuit 130 on the adhesive layer 112 are similar to the descriptions in FIG. 9 to FIG. 11, detailed descriptions thereof will be omitted.

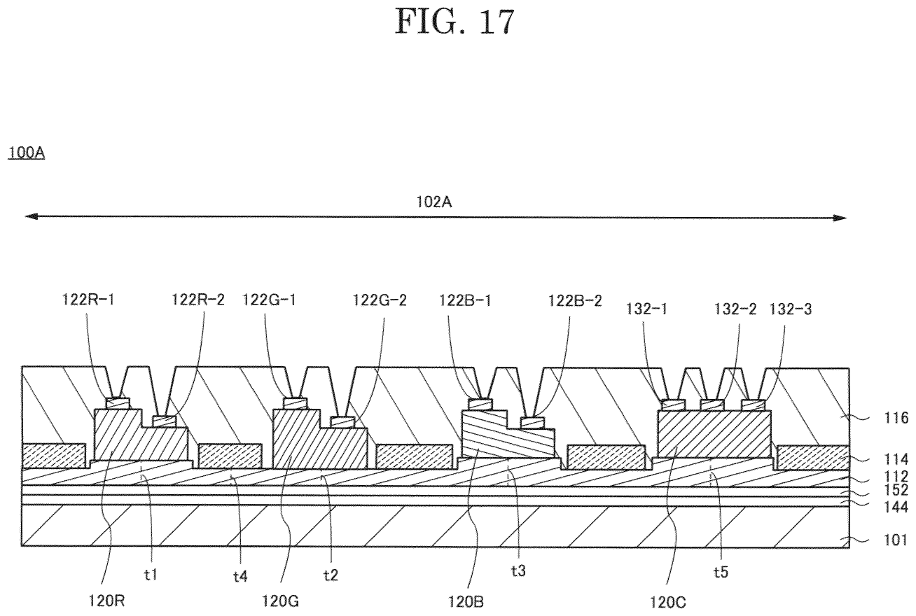

FIG. 17 is a diagram illustrating a step of forming the insulating layer 116 on the LED chip 120 and the pixel circuit 130. The insulating layer 116 is formed in the display region 102 and the peripheral region 103. A material and thickness of the insulating layer 116 is as described in FIG. 12. Next, a contact hole is formed in the insulating layer 116. This causes the terminals 122R-1, 122R-2, 122G-1, 122G-2, 122B-1, 122B-2, 132-1 and 132-2 to be exposed from the insulating layer 116. In addition, the wiring or terminal of the driving circuit is exposed from the insulating layer 116. Finally, the wirings 118-1 to 118-8 are formed on the insulating layer 116. A conductive film is formed on the insulating layer 116 and appropriately patterned to form the wirings 118-1 to 118-8. This allows the LED chip 120 and the pixel circuit 130 to be connected by the wiring 118. In addition, the pixel circuit 130 and the driving circuit can be connected by the wiring 118.

Through the above steps, the display device 100A according to an embodiment of the present invention shown in FIG. 14 can be manufactured.

According to the display device 100A of the present embodiment, even when the height of the LED chip 120R, the height of LED chip 120G, and the height of LED chip 120B are different for each color, the connecting surface between the terminals 122-1 and 122-2 and the wiring 118 can be made uniform. As a result, the depth of the contact hole formed in the insulating layer 116 can be made substantially the same regardless of the height of the LED chip 120. Therefore, it is easy to form the contact hole in the insulating layer 116, and it is possible to suppress the wiring from breaking when forming the wiring 118.

Each of the embodiments described above as an embodiment of the present invention can be appropriately combined and implemented as long as no contradiction is caused. Furthermore, the addition, deletion, or design change of components, or the addition, deletion, or condition change of processes as appropriate by those skilled in the art based on the display device of each embodiment are also included in the scope of the present invention as long as they are provided with the gist of the present invention.

Furthermore, it is understood that, even if the effect is different from those provided by each of the above-described embodiments, the effect obvious from the description in the specification or easily predicted by persons ordinarily skilled in the art is apparently derived from the present invention.

What is claimed is:

1. A display device comprising:
a substrate provided on a driving circuit;
an adhesive layer covering the substrate;
a first LED chip provided on the adhesive layer;
a pixel circuit provided on the adhesive layer, separated from the first LED chip;
a light shielding layer provided on the adhesive layer, and a first opening of the same shape as that of the first LED chip when viewed in a plan view and a second opening of the same shape as that of the pixel circuit when viewed in a plan view;
an insulating layer covering the driving circuit and the pixel circuit; and
a first wiring provided on the insulating layer, connected to the first LED chip and the pixel circuit,
wherein the first wiring overlaps the light shielding layer.

2. The display device according to claim 1, further comprising:
a second wiring provided on the insulating layer, connected to the pixel circuit and the driving circuit,
wherein the first LED chip and the pixel circuit is provided in a display region;
the driving circuit is provided on a peripheral region surrounding the display region, and
the second wiring is electrically connected to the driving circuit in the peripheral region via a contact hole in the insulating layer.

3. The display device according to claim 2, wherein
a height of the pixel circuit differs from a height of the first LED chip, and
a thickness of a first region where the first LED chip is arranged is different from a thickness of the second region where the pixel circuit is arranged.

4. The display device according to claim 3, wherein
a height of a connection surface of the first LED chip to the first wiring is the same as the height of a connection surface of the pixel circuit to the second wiring.

5. The display device according to claim 2, further comprising:
a second LED chip provided on the adhesive layer in the display region and having a different emission color from the first LED chip; and
a third wiring provided on the insulating layer to connect the second LED chip to the pixel circuit,
wherein the light shielding layer further has a third opening of the same shape as that of the second LED chip when viewed in a plan view.

6. The display device according to claim 5, wherein
a height of the second LED chip differs from a height of the first LED chip, and
a thickness of the first region where the first LED chip is arranged is different from a thickness of the third region where the second LED chip is arranged in the adhesive layer.

7. The display device according to claim 6, wherein
a height of a connection surface of the first LED chip to the first wiring is the same as a height of a connection surface of the second LED chip to the third wiring.

8. The display device according to claim 1, wherein
a surface of the light shielding layer has fluorine or a fluorine compound.

9. The display device according to claim 1, wherein
a thickness of the shielding layer is thinner than a height of the first LED chip.

10. A method for manufacturing a display device comprising:
forming an adhesive layer provided on a substrate with a driving circuit;
forming a light shielding layer having a plurality of openings and a liquid repellent surface formed on the adhesive layer;
applying a solvent on the adhesive layer within the plurality of openings;
arranging a first LED chip in contact with the solvent in a first opening of the plurality of openings;
arranging a second LED chip in contact with the solvent in a second opening of the plurality of openings;
adhering the adhesive layer to the first LED chip and the pixel circuit to the adhesive layer by evaporating the solvent;
forming an insulating layer on the driving circuit, the first LED chip, and the pixel circuit;
forming a first contact hole reaching the first LED chip and a second contact hole reaching the pixel circuit in the insulating layer; and
forming a first wiring on the insulating layer to connect the first LED chip and the pixel circuit through the first contact hole and the second contact hole.

11. The method for manufacturing a display device according to claim 10, wherein
a height of the first LED chip differs from the height of the pixel circuit, and
the adhesive layer is formed so that a thickness of a first region where the first LED chip is provided is different from a thickness of a second region where the pixel circuit is provided.

12. The method for manufacturing a display device according to claim 10, further comprising:
arranging the second LED chip in contact with the solvent in the third opening of the plurality of openings after mounting the first LED chip, and
adhering the adhesive layer to the second LED chip to the adhesive layer by evaporating the solvent.

13. The method for manufacturing a display device according to claim 12, wherein
a height of the first LED chip differs from a height of the second LED chip, and
the adhesive layer is formed so that a thickness of the first region where the first LED chip is provided and a thickness of the third region where the second LED chip is provided are different.

14. The method for manufacturing a display device according to claim 10, wherein
a surface contact angle of the light shielding layer having liquid repellency is 90° or more.

15. The method for manufacturing a display device according to claim 10, wherein
a plasma treatment is performed using a gas containing fluorine or a fluorine compound after forming a black resin having insulating properties on the adhesive layer.
